(19) United States
(12) Patent Application Publication
(10) Pub. No.: US 2025/0230540 A1
(43) Pub. Date: Jul. 17, 2025

(54) SEAM PERFORMANCE IMPROVEMENT FOR LARGE AREA GAPFILL

(71) Applicant: Applied Materials, Inc., Santa Clara, CA (US)

(72) Inventors: Supriya Ghosh, San Jose, CA (US); Susmit Singha Roy, Campbell, CA (US); Abhijit Basu Mallick, Sunnyvale, CA (US); Nitin K. Ingle, San Jose, CA (US); Diwakar Kedlaya, San Jose, CA (US); Priya Chouhan, Fremont, CA (US)

(73) Assignee: Applied Materials, Inc., Santa Clara, CA (US)

(21) Appl. No.: 18/410,634

(22) Filed: Jan. 11, 2024

(51) Int. Cl. C23C 16/04; C23C 16/24; C23C 16/32; C23C 16/34; C23C 16/40; C23C 16/455; H01L 21/02

(52) U.S. Cl. CPC C23C 16/045; C23C 16/24; C23C 16/325; C23C 16/342; C23C 16/402; C23C 16/45536; H01L 21/02164; H01L 21/02274; H01L 21/0228

(57) ABSTRACT

Methods of filling a feature on a semiconductor substrate may include performing a process to fill the feature on the semiconductor substrate by repeatedly performing first operations. First operations can include providing a silicon-containing precursor. First operations can include contacting the substrate with the silicon-containing precursor to form a silicon-containing material within the feature defined on the substrate. First operations can include purging the semiconductor processing chamber. First operations can include providing an oxygen-containing precursor. First operations can include contacting the substrate with the oxygen-containing precursor to form a silicon-and-oxygen-containing material within the feature defined on the substrate. At least some portions of the first operations can be performed with a frequency characteristic, a power characteristic, and a pressure characteristic.

### TECHNICAL FIELD

The present technology relates to methods of semiconductor processing. More specifically, the present technology relates methods of forming materials on semiconductor structures.

### BACKGROUND

Integrated circuits are made possible by processes which produce intricately patterned material layers on substrate surfaces. Producing patterned material on a substrate requires controlled methods for forming and removing material. As device sizes continue to reduce, and device complexity continues to increase, producing structures has become increasingly complex. Developing structures may take many more operations to produce the complex patterning and material integration. Additionally, complex patterning and material integration at intersections between materials, including similar materials, may take more operations to prevent potential deformations or unwanted formations.

Thus, there is a need for improved systems and methods that can be used to produce high quality devices and structures. These and other needs are addressed by the present technology.

### SUMMARY

In some embodiments, a method of filling a feature on a semiconductor substrate, the method can include performing a process to fill the feature on the semiconductor substrate in a semiconductor processing chamber, wherein the process comprises repeatedly performing first operations including: providing a silicon-containing precursor; contacting the substrate with the silicon-containing precursor to form a silicon-containing material within the feature defined on the substrate; purging the semiconductor processing chamber; providing an oxygen-containing precursor plasma with a power characteristic and at a pressure characteristic based at least in part on a frequency characteristic of a plasma power source of the semiconductor processing chamber, wherein the power characteristic, the pressure characteristic, and the frequency characteristic are configured to increase radical density of the oxygen-containing precursor plasma and provide kinetic energy within a range to ions of the oxygen-containing precursor plasma; and contacting the substrate with the oxygen-containing precursor to form a silicon-and-oxygen-containing material within the feature defined on the substrate.

In some embodiments, a method of filling a feature on a semiconductor substrate, the method includes performing a process to fill the feature on the semiconductor substrate in a semiconductor processing chamber, wherein the process comprises repeatedly performing first operations including: providing a silicon-containing precursor; contacting the substrate with the silicon-containing precursor to form a silicon-containing material within the feature defined on the substrate; purging the semiconductor processing chamber; providing an oxygen-containing precursor; and contacting the substrate with the oxygen-containing precursor by forming a plasma with a frequency characteristic and a power characteristic and at a pressure characteristic, wherein the power characteristic, the pressure characteristic, and the frequency characteristic are configured to provide sufficient radical density and kinetic energy, wherein contacting the substrate with the oxygen-containing precursor forms a silicon-and-oxygen-containing material within the feature defined on the substrate.

In some embodiments, a method of filling a feature on a semiconductor substrate, the method includes performing a process to fill the feature on the semiconductor substrate in a semiconductor processing chamber, wherein the process comprises repeatedly performing first operations at a first pressure level, the first operations including: providing a silicon-containing precursor; contacting the substrate with the silicon-containing precursor to form a silicon-containing material within the feature defined on the substrate; purging the semiconductor processing chamber; providing an oxygen-containing precursor; and providing an oxygen-containing precursor. The process to fill the feature further can further include second operations, the second operations including applying a silicon-containing-and-non-oxide-containing material via a conformal application process.

In any embodiments, any and all of the following features can be implemented in any combination and without limitation. In some embodiments, providing the oxygen-containing precursor with the power characteristic, pressure characteristic, and frequency characteristic can cause a gap in the feature to close by causing a first side of the silicon-and-oxygen-containing material within the feature to bond with a second side of the silicon-and-oxygen-containing material within the feature. In some embodiments, forming the silicon-containing material within the feature can include forming an atomic layer of silicon on an exposed surface of the feature. In some embodiments, forming the silicon-and-oxygen-containing material within the feature can include providing oxygen to the atomic layer of silicon. In some embodiments, contacting the silicon-and-oxygen-containing material with the oxygen-containing precursor with the frequency characteristic, the power characteristic, and at the pressure characteristic can cause a gap in the feature to close by causing a first side of the silicon-and-oxygen-containing material within the feature to bond with a second side of the silicon-and-oxygen-containing material within the feature. In some embodiments, the frequency characteristic can be within a range of about 25 MHz to 30 MHz. In some embodiments, the pressure characteristic can be within a second range of about 4 Torr to about 15 Torr. In some embodiments, the power characteristic can be within a third range of about 1500 Watts and about 3000 Watts. In some embodiments, providing the oxygen-containing precursor plasma can include providing the oxygen-containing precursor plasma at a second frequency characteristic of a second plasma power source of the semiconductor processing chamber, the second frequency characteristic being with in a fourth range of about 1 kHz to 1 MHz. In some embodiments, the feature can be characterized by an aspect ratio of greater than or about 10:1. In some embodiments, the oxygen-containing precursor can include 02. In some embodiments, the power characteristic can be within a range of about 1000 Watts and about 2000 Watts. In some embodiments, the pressure characteristic can be within a second range of about 8 Torr to about 15 Torr. In some embodiments, the frequency characteristic can be within a third range of about 10 MHz to 15 MHz. In some embodiments, the process can be performed at a temperature greater than or about 400° C. In some embodiments, the conformal application process can be a chemical vapor deposition process. In some embodiments, the conformal application process can be an atomic layer deposition process. In some embodiments, the silicon-containing-and-non-oxide-containing material can include at least one of: SiC, SiN, and high-purity silicon. In some embodiments, the second operations can be performed in the semiconductor processing chamber.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIGS. 2A-2D show exemplary schematic cross-sectional structures in which material layers are produced according to some embodiments of the present technology.

FIGS. 3A-3B show exemplary schematic cross-sectional structures in which material layers are produced according to some embodiments of the present technology.

FIG. 4 shows operations in a semiconductor processing method according to some embodiments of the present technology.

FIGS. 5A-5B show exemplary schematic cross-sectional structures in which material layers are produced according to some embodiments of the present technology.

FIG. 6 shows operations in a semiconductor processing method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Silicon material may be used in semiconductor device manufacturing for a number of structures and processes. In gap filling operations, some processing may utilize plasma-enhanced deposition under process conditions in attempt to increase the directionality of the deposition, which may allow the deposited material to better fill features on the substrate. However, in some deposition processes, the deposited material in certain kinds of features may be characterized by seams when the deposited material meets up with other deposited material. For example, if a feature represents a significantly large depth to width ratio (meaning the feature is deep but the size of an opening for the feature is relatively small in width), deposited material from the sides of the feature can meet up and create seams. The seams can be indicative that the gapfill process has been unsuccessful in properly filling the gaps and can lead to structural problems as further semiconductor manufacturing processes are conducted on the substrate.

As feature sizes continue to shrink, depositions may be challenged for narrow features, which may be further characterized by higher aspect ratios. For example, as material is deposited material in a feature with a high aspect ratio, seams can form between the deposited material on a first side of the feature and the deposited material on a second side of the feature. Seams can also be referred to as gaps or voids. Seams represent that the deposited material on the sides of the features do not bond when the deposited material on the sides meet. These seams may not be noticeable by tools because the seams can be on the atomic level. Nonetheless, an etchant used on the deposited material (such as a buffer oxide etchant on a silicon oxide deposited material) can expose and/or demonstrate that there is a seam between the deposited material on the sides of the feature.

The present technology may overcome these limitations by performing an atomic layer deposition of material with sufficient high radical density and optimized kinetic energy that may improve large gapfill operations by eliminating and/or reducing seams in the gapfill material. Sufficiently high radical density and optimized kinetic energy can be achieved by careful tuning of power being supplied to the plasma and pressure in the semiconductor fabrication chamber based on the frequencies of the plasma power source. Increasing the radical density in the gapfill material can provide more bonding sites for the two sides of the deposited material to aid in bonding the two sides. Sufficient kinetic energy can provide the sufficient energy for the bonding of the two sides when there are sufficient radicals. Too much kinetic energy can cause damage within the gapfill material. Additionally, a gapfill operation can include partially filling the gap by forming layers of a compressive film and then filling the rest of the gap by applying a non-oxide silicon material via a conformal process. In this way, the gapfill can have both compressive properties and a seam does not form between the two sides of the non-oxide silicon material at the center of the gapfill.

Although the remaining disclosure will routinely identify specific deposition processes utilizing the disclosed technology, and will describe one type of semiconductor processing chamber, it will be readily understood that the processes described may be performed in any number of semiconductor processing chambers. Additionally, the present technology may be applicable to any number of semiconductor processes, beyond the exemplary process described below. Accordingly, the technology should not be considered to be so limited as for use with these specific deposition processes or chambers alone. The disclosure will discuss one possible chamber that may be used to perform processes according to embodiments of the present technology before methods of semiconductor processing according to the present technology are described.

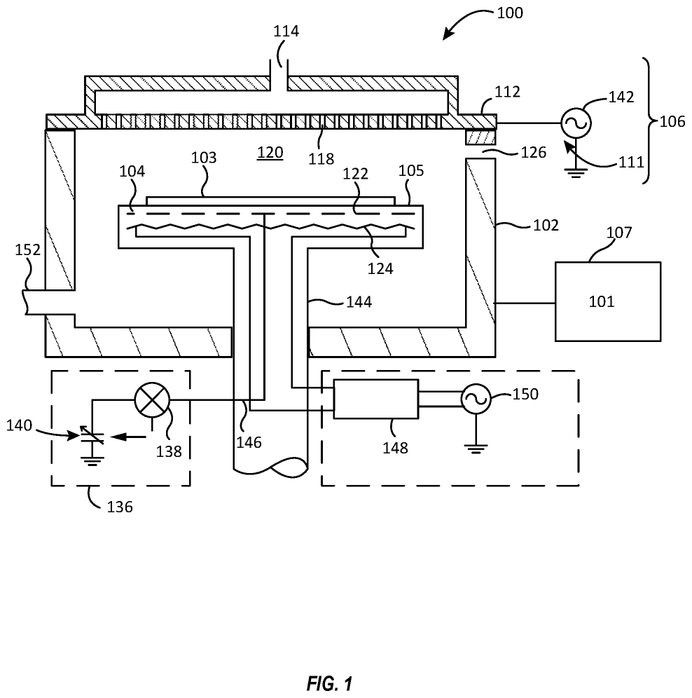

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, along a vertical axis, where a shaft 144 of the substrate support 104 may be located, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power,

RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Upon energizing a plasma in the processing volume 120, a potential difference may be established between the plasma and the first electrode 122. The electronic controller 140 may then be used to adjust the flow properties of the ground paths represented by the tuning circuit 136. A set point may be delivered to the tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the tuning circuit 136 in a closed loop. A set point for current or voltage, depending on the type of sensor used, may be installed in each sensor, and the sensor may be provided with control software that determines an adjustment to the electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

Processing chamber 100 may be utilized in some embodiments of the present technology for processing methods that may include bottom-up deposition of materials for semiconductor structures. It is to be understood that the chamber described is not to be considered limiting, and any chamber that may be configured to perform operations as described may be similarly used.

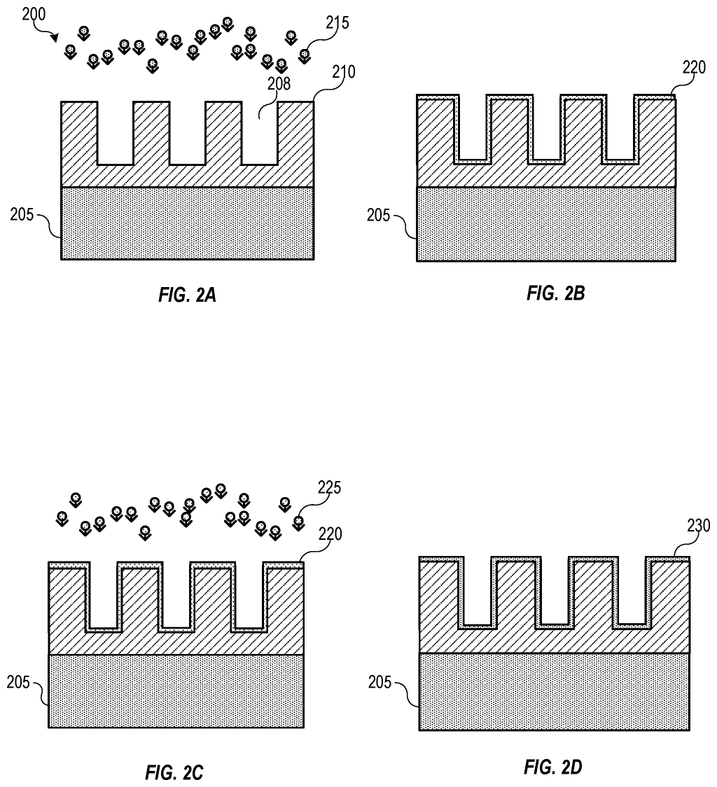

Processing chamber 100 may be utilized in some embodiments of the present technology for processing methods that may include formation, etching, or conversion of materials for semiconductor structures. It is to be understood that the chamber described is not to be considered limiting, and any chamber that may be configured to perform operations as described may be similarly used. FIGS. 2A-2D schematically illustrate exemplary operations in processing methods according to some embodiments of the present technology. The methods may be performed in a variety of processing chambers and on one or more mainframes or tools, including processing chamber 100 described above. The processing methods may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. It is to be understood that the figures illustrate only partial schematic views, and a structure 200 or a substrate 205 may contain any number of additional materials and features having a variety of characteristics and aspects as shown in the figures.

The substrate 205 may include any number of materials used in semiconductor processing. The substrate material may be or include silicon, germanium, dielectric materials including silicon oxide or silicon nitride, metal materials, or any number of combinations of these materials. The substrate 205 may include one or more substrate features formed in the substrate 205. The substrate 205 may include one or more materials 210 in which one or more features may be formed. The features may be characterized by any shape or configuration according to the present technology. In some embodiments, the features may be or include a trench structure 208 or aperture formed within the substrate. In some embodiments, the features may be characterized by any aspect ratios, or the height-to-width ratio of the structure, although in some embodiments the materials may be characterized by larger aspect ratios, which may not allow seam free or void free deposition utilizing conventional technology or methodology. For example, in some embodiments the aspect ratio of any layer of an exemplary structure may be greater than or about 10:1, greater than or about 11:1, greater than or about 12:1, greater than or about 13:1, greater than or about 14:1, greater than or about 15:1, greater than or about 16:1, or greater. Additionally, the features may be characterized by a reduced width, such as less than or about 2.0 microns, less than or about 1.9 microns, less than or about 1.8 microns, less than or about 1.7 microns, less than or about 1.6 microns, less than or about 1.5 microns, less than or about 1.4 microns, less than or about 1.3 microns, less than or about 1.2 microns, less than or about 1.1 microns, less than or about 1.0 microns, less than or about 0.9 microns, less than or about 0.8 microns, less than or about 0.7 microns, less than or about 0.6 microns, less than or about 0.5 microns, less than or about 0.4 microns, less than or about 0.3 microns, less than or about 0.2 microns, less than or about 0.1 microns, or less, including any fraction of any of the stated numbers. As such, the features may be characterized with a height, such as less than or about 20.0 microns, less than or about 19.0 microns, less than or about 18.0 microns, less than or about 17.0 microns, less than or about 16.0 microns, less than or about 15.0 microns, less than or about 14.0 microns, less than or about 13.0 microns, less than or about 12.0 microns, less than or about 11.0 microns, less than or about 10.0 microns, less than or about 9.0 microns, less than or about 8.0 microns, less than or about 7.0 microns, less than or about 6.0 microns, less than or about 5.0 microns, less than or about 4.0 microns, less than or about 3.0 microns, less than or about 2.0 microns, less than or about 1.0 microns, less than or about 0.8 microns, or less, including any fraction of any of the stated numbers. This combination of high aspect ratios and minimal widths may frustrate many conventional deposition operations to bond the deposited material on one side of the feature to the deposited material on another side of the feature.

The methods described herein may include additional operations prior to initiation of the operations to gapfill the seam. For example, additional processing operations may include forming structures on a semiconductor substrate 205, which may include both forming and removing material. For example, transistor structures, memory structures, or any other structures may be formed. Prior processing operations may be performed in the chamber in the methods for gapfilling seams described herein may be performed, or processing may be performed in one or more other processing chambers prior to delivering the substrate into the semiconductor processing chamber or chambers in which the methods for gapfilling seams described herein may be performed. Regardless, the methods for gapfilling seams described herein may optionally include delivering a semiconductor substrate 205 to a processing region of a semiconductor processing chamber, such as processing chamber 100 described above, or other chambers that may include components as described above. The substrate 205 may be deposited on a substrate support, which may be a pedestal such as substrate support 104, and which may reside in a processing region of the semiconductor processing chamber, such as a processing volume.

Embodiments of the present disclosure may form silicon-containing and/or silicon-and-oxygen-containing material through atomic layer deposition. The material may be formed by alternatingly providing precursors such that the material intermittently forms. To deposit silicon-and-oxygen-containing material, the precursors may include silicon and oxygen. The precursor including silicon may be referred to as a silicon-containing precursor. The precursor including oxygen may be referred to as an oxygen-containing precursor. In some embodiments, a silicon-and-oxygen-containing material may be formed through atomic layer deposition. To incorporate oxygen, the precursors may further include oxygen. For example, an oxygen-containing precursor may be intermittently provided during the formation. Alternatively, the silicon-containing precursor may further include oxygen. For example, the silicon-containing precursor may be a silicon-and-oxygen-containing precursor.

Embodiments of the present disclosure may to gapfill seams formed between sides of silicon-and-oxygen-containing material along the sides of a feature. In some embodiments, gapfilling seams may be done through atomic layer deposition. Gapfilling seams may be done by alternatingly providing precursors such that the material intermittently forms. One precursor can include silicon and may be referred to as a silicon-containing precursor. Another precursor may include oxygen and may be referred to as an oxygen-containing precursor.

In embodiments, the silicon-containing precursor may be any silicon-containing material useful in semiconductor processing, such as in atomic layer deposition processes. Exemplary silicon-containing precursors may be or include, but are not limited to, silane, disilane, or other aminosilanes, or other organosilanes including cyclohexasilanes, silicon tetrafluoride, silicon tetrachloride, dichlorosilane, tetraethyl orthosilicate (TEOS), tetramethyldisiloxane (TMDSO), hexamethyldisiloxane (HMDSO), hexamethyldisilazane (HMDSN), and silicon tetrakis (ethylmethyamide) (TEMASi), alkylaminosilane, trisilylamine, alkylaminodisilane, alkylsilane, alkyloxysilane, alkylsilanol, and alkyloxysilanolas well as any other silicon-containing precursors that may be used in silicon-containing material formation. In some embodiments, the silicon-containing precursor may include a halogen, such as chlorine, bromine, iodine, or any other halogen. Additional silicon-containing precursors may be or include any of the following materials:

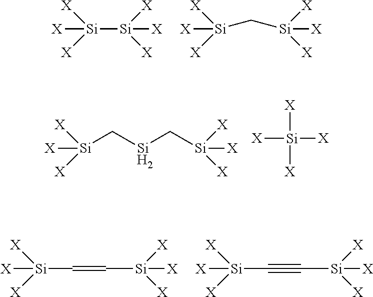

In the above materials, each X may be independently selected from chlorine, bromine, iodine, hydrogen, OR, NR₂, NCO, NCS, or CN, where R may be an alkyl.

The oxygen-containing precursor may be any oxygen-containing material useful in semiconductor processing, such as in atomic layer deposition processes. For example, the oxygen-containing precursor may be molecular oxygen (O₂), ozone (O₃), N₂O, and/or other similar materials. In embodiments, in order to maintain oxygen content in the formed material, the oxygen-containing precursor may be diluted with another precursor such as an inert precursor. The oxygen-containing precursor may be less than or about 50% based on the oxygen-containing precursor and the inert precursor.

The methods described herein for gapfilling seams may include providing a first precursor to the semiconductor processing chamber, such as a processing region of the semiconductor processing chamber. Optionally, a plasma of the first precursor may be generated. It is also contemplated that a plasma of the first precursor may be generated prior to providing the plasma of the first precursor to the semiconductor processing chamber. In some embodiments, the first precursor is a silicon-containing precursor. Referring to FIG. 2A, the first precursor may have at least one reactive group that can form a bond with a group attached to a surface of the substrate 205 or one or more materials 210 in the processing region. Molecules of the first precursor 215 (for example, a silicon-containing precursor) may react with the surface groups to form bonds linking the first precursor molecule to the surface of the substrate 205 or one or more materials 210. The reactions between molecules of the first precursor 215 and the groups on the surface of the substrate 205 or one or more materials 210 may continue until most or all the surface groups are bonded to a reactive group on molecules of the first precursor 215. As shown in FIG. 2B, a first portion of a silicon-containing material 220 may be formed from the first precursor. The formation of the silicon-and-oxygen-containing material 220 may block further reaction between molecules of the first precursor 215 in the first precursor effluent and the substrate 205 or one or more materials 210.

The first precursor may remain in the processing region for a period of time to nearly or completely form the silicon-containing material 220. To form the silicon-containing material according to embodiments of the present technology, precursors may be delivered in alternating pulses to grow the material. In some embodiments, the pulse time of the first precursor may be greater than or about 0.5 seconds, greater than or about 1 second, greater than or about 2 seconds, greater than or about 3 seconds, greater than or about 4 seconds, greater than or about 5 seconds, greater than or about 10 seconds, greater than or about 20 seconds, greater than or about 40 seconds, greater than or about 60 seconds, greater than or about 80 seconds, greater than or about 100 seconds, or more.

The methods described herein may also include an operation to purge or remove the first precursor from the processing region following the formation of the silicon-containing material 220. The methods described herein may include halting a flow of the first precursor prior to purging the first precursor from the semiconductor processing chamber. The first precursor may be removed by pumping the first precursor out of the processing region for a period of time ranging from about 10 seconds to about 100 seconds. Additional exemplary time ranges may include about 20 seconds to about 50 seconds, and 25 seconds to about 45 seconds, among other exemplary time ranges. However, in some embodiments, increased purge time may begin to remove reactive sites, which may reduce uniform formation. Accordingly, in some embodiments the purge may be performed for less than or about 60 seconds, and may be performed for less than or about 50 seconds, less than or about 40 seconds, less than or about 30 seconds, or less. In some embodiments, a purge gas may be introduced to the processing region to assist in the removal of the effluents. Exemplary purge gases include helium and nitrogen, among other purge gases.

After the removal of the first precursor, a second precursor may be provided to the semiconductor processing chamber as shown in FIG. 2C. Optionally, a plasma of the second precursor may be generated. It is also contemplated that a plasma of the second precursor may be generated prior to providing the plasma of the second precursor to the semiconductor processing chamber. The second precursor may have at least one reactive group that can form bonds with unreacted reactive groups of the first precursor that formed the silicon-containing material 220. In some embodiments, the second precursor is an oxygen-containing precursor. Molecules of the second precursor 225 may react with the unreacted reactive groups of the first precursor to form bonds linking molecules of the second precursor 225 to molecules of the first precursor 215. The reactions between molecules of the second precursor 225 and molecules of the first precursor 215 may continue until most or all the unreacted reactive groups on molecules of the first precursor 215 have reacted with molecules of the second precursor 225. As shown in FIG. 2D, the contact between the second precursor and the silicon-containing material 220 may form a silicon-and-oxygen-containing material 230, such as silicon oxide (SiO, or SiO₂). The formation of the silicon-and-oxygen-containing material 230 may block further reaction between molecules of the second precursor 225 in the second precursor effluent and the silicon-and-oxygen-containing material 220.

Similar to the first precursor, the second precursor may remain in the processing region for a period of time to nearly or completely form the silicon-and-oxygen-containing material 230. As previously discussed, to form silicon-and-oxygen-containing material according to embodiments of the present technology, precursors may be delivered in alternating pulses to grow the material. In some embodiments, the pulse time of the second precursor may be greater than or about 0.5 seconds, greater than or about 1 second, greater than or about 2 seconds, greater than or about 3 seconds, greater than or about 4 seconds, greater than or about 5 seconds, greater than or about 10 seconds, greater than or about 20 seconds, greater than or about 40 seconds, greater than or about 60 seconds, greater than or about 80 seconds, greater than or about 100 seconds, or more.

In some embodiments, the first precursor may be pulsed for longer periods of time than the second precursor. By increasing the residence time of the first precursor, improved adhesion may be produced across the substrate 205 or one or more materials 210. The second precursor may then more readily react with the ligands of the first precursor, and thus the second precursor may be pulsed for less time, which may improve throughput. For example, in some embodiments, the second precursor may be pulsed for less than or about 90% of the time the first precursor is pulsed. The second precursor may also be pulsed for less than or about 80% of the time the first precursor is pulsed, less than or about 70% of the time the first precursor is pulsed, less than or about 60% of the time the first precursor is pulsed, less than or about 50% of the time the first precursor is pulsed, less than or about 40% of the time the first precursor is pulsed, less than or about 30% of the time the first precursor is pulsed, or less.

The methods described herein can also include an operation to purge or remove the second precursor effluents from the processing region following the formation of the silicon-containing material 230. The methods described herein may include halting a flow of the second precursor prior to pursing the second precursor. The second precursor may be removed by pumping them out of the processing region for a period of time ranging from about 10 seconds to about 100 seconds. Additional exemplary time ranges may include about 20 seconds to about 50 seconds, and 25 seconds to about 45 seconds, among other exemplary time ranges. In some embodiments, a purge gas may be introduced to the processing region to assist in the removal of the effluents. Exemplary purge gases include helium and nitrogen, among other purge gases.

In embodiments, there may be a determination of whether a target thickness of the as-deposited material on the substrate 205 or one or more materials 210 has been achieved following one or more cycles of forming the silicon-and-oxygen-containing material 230. If a target thickness of the as-deposited material has not been achieved, another cycle of providing the first precursor and second precursor may be performed. If a target thickness of the as-deposited material has been achieved, another cycle of providing the first precursor and second precursor may not be started. Exemplary numbers of cycles for the formation of the silicon-and-oxygen-containing material 230 may include 1 cycle, or may include greater than 2 cycles, 5 cycles, 10 cycles, 25 cycles, 50 cycles, 100 cycles, 1000 cycles, 2000 cycles, 3000 cycles, 4000 cycles, 5000 cycles, 6000 cycles, 7000 cycles, 8000 cycles, 9000 cycles, 10000 cycles or more. Additional exemplary ranges for the number of cycles may include 50 cycles to 2000 cycles, 50 cycles to 1000 cycles, and 100 cycles to 750 cycles, 1000 to 2000 cycles, 2000 to 3000 cycles, 3000 to 4000 cycles, 4000 to 5000 cycles, 5000 to 6000 cycles, 6000 to 7000 cycles, 7000 to 8000 cycles, 8000 to 9000 cycles, 9000 to 10000 cycles, and/or any combination of these ranges. For example, some embodiments may use between 6000 and 8000 cycles for a 1 μm wide gap structure. Exemplary ranges of target thickness to discontinue further cycles of forming silicon-and-oxygen-containing material 230 include less than or about 1.0 microns. Additional exemplary thickness ranges may include less than or about 1.0 microns, less than or about 0.9 microns, less than or about 0.8 microns, less than or about 0.7 microns, less than or about 0.6 microns, less than or about 0.5 microns, less than or about 0.4 microns, less than or about 0.3 microns, less than or about 0.2 microns, less than or about 0.1 microns, or less, including any fraction of any of the stated numbers.

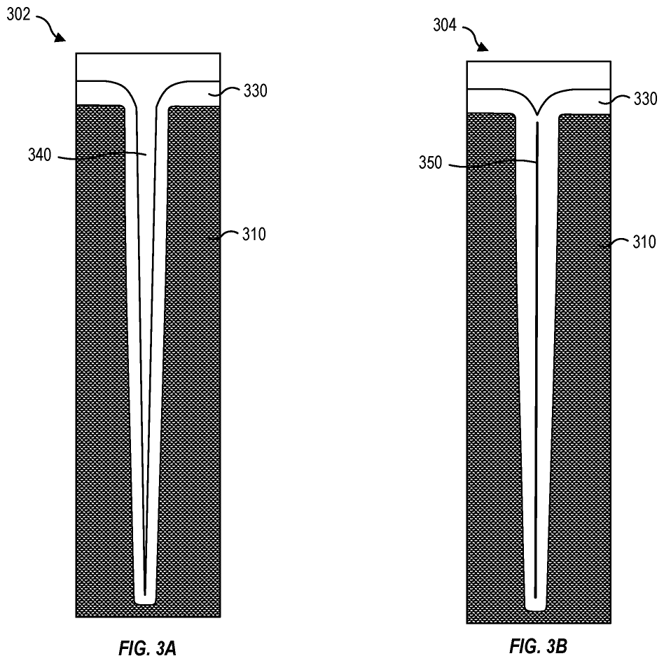

FIGS. 3A-3B schematically illustrate how a seam may be formed during processing methods according to some embodiments of the present technology. Cross-section 302 and cross-section 304 schematically illustrate how a seam 350 is formed by the silicon-and-oxygen containing material 330 (for example, the silicon-and-oxygen-containing material 230 of FIG. 2) deposited into the one or more materials 310 (for example, the one or more materials 210 of FIG. 2). In FIG. 3A, a space 340 can be seen between the two sides of the silicon-and-oxygen-containing material 330 deposited into the feature. The silicon-and-oxygen-containing material 330 can be roughly uniform across the surface of the one or more materials 310.

In FIG. 3B, as more silicon-and-oxygen-containing material 330 is deposited, a seam 350 can be formed such that the two sides of the silicon-and-oxygen-containing material 330 do not bond. The seam 350 can be formed because the layers of the silicon-and-oxygen-containing material 330 build up from the sides of the feature. As noted above, the seam 350 may not be noticeable because the seam may be on the atomic and/or molecular level. However, if an etchant (for example, a buffer oxide etchant that etches the silicon-and-oxygen-containing material 330) is applied to the silicon-and-oxygen-containing material 330 along the seam 350, the seam 350 can become noticeable as material from the silicon-and-oxygen-containing material 330 around the seam 350 is etched away.

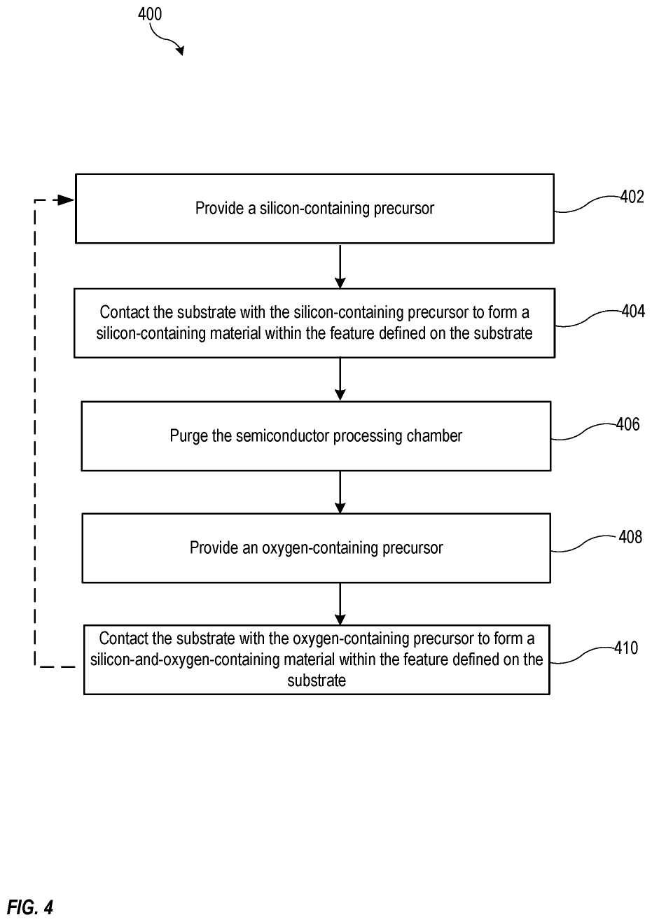

FIG. 4 illustrates an example flowchart 400 of a method of filling a feature on a semiconductor substrate in a way that reduces a seam and/or eliminates a seam as described herein. This method may be carried out by the controller that generates the signals for controlling the processing chamber and other elements as illustrated above in FIGS. 2A-2D and 3A-3B. This method may be carried out by a controller having processors that execute instructions to perform these operations.

The method may include performing a process to fill the feature on the semiconductor substrate in a semiconductor processing chamber. The process can include repeatedly performing first operations as described herein. For example, the first operations can be repeated for a number of cycles as described herein. Additionally, parts of the first operations can be repeated for different numbers of cycles such that one part of the first operations can be repeated for a first number of cycles while a second part of the first operations can be repeated for a second number of cycles. In some embodiments, the feature can be characterized by an aspect ratio of greater than or about 10:1 as described herein.

The first operations may include providing a silicon-containing precursor (402) to a semiconductor processing chamber (for example, the processing chamber 100 of FIG. 1) as described in relation to at least FIGS. 2A-2D. The silicon-containing precursor can be a first precursor as described herein.

The first operations may include contacting the substrate with the silicon-containing precursor to form a silicon-containing material within the feature defined on the substrate (404) as described herein. Forming the silicon-containing material within the feature can include forming an atomic layer of silicon on an exposed surface of the feature. The exposed surface of the feature can include two or more sides of the feature, for example sides that are opposite of each other.

The formation of the silicon-containing material 220 (either or both of the providing of the silicon-containing precursor and the contacting of the substrate with the silicon-containing precursor) can be done at a variety of temperatures (for example, the temperature of the substrate 205, the temperature of the processing chamber, and/or the temperature of the precursors that flow into the processing region). Exemplary temperatures for the substrate, processing chamber, and/or precursors during the operations described herein may be greater than or about 50° C., greater than or about 75° C., greater than or about 100° C., greater than or about 125° C., greater than or about 150° C., greater than or about 175° C., greater than or about 200° C., greater than or about 250° C., greater than or about 300° C., greater than or about 350° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., greater than or about 625° C., greater than or about 650° C., greater than or about 675° C., greater than or about 700° C., greater than or about 725° C., greater than or about 750° C., greater than or about 775° C., greater than or about 800° C., greater than or about 825° C., greater than or about 850° C., greater than or about 875° C., greater than or about 900° C., greater than or about 925° C., greater than or about 950° C., greater than or about 975° C., greater than or about 1000° C., or higher. In some embodiments, exemplary temperatures can range from 400° C.-1000° C. In some embodiments, exemplary temperatures can range from 400° C.-700° C. In some embodiments, exemplary temperatures can range from 600° C.-1000° C. By maintaining the substrate temperature elevated, such as above or about 400° C. in some embodiments, an increased number of nucleation sites may be available along the substrate 205, which may improve formation and reduce void formation by improving coverage at each location.

The formation of the silicon-containing material 220 (either or both of the providing of the silicon-containing precursor and the contacting of the substrate with the silicon-containing precursor) can be done at a variety of pressures in the processing chamber. Exemplary pressures in the processing region may range from about 1 Torr to about 100 Torr. In some embodiments, the pressures in the processing region may range from 2 to 20 Torr. In embodiments, the pressure may be less than or about 20 Torr, such as less than or about 19 Torr, less than or about 18 Torr, less than or about 17 Torr, less than or about 16 Torr, less than or about 15 Torr, less than or about 14 Torr, less than or about 13 Torr, less than or about 12 Torr, less than or about 11 Torr, less than or about 10 Torr, less than or about 9 Torr, less than or about 8 Torr, less than or about 7 Torr, less than or about 6 Torr, less than or about 5 Torr, less than or about 4 Torr, less than or about 3 Torr, less than or about 2 Torr, less than or about 1 Torr, or less. In some embodiments, part of the processes in the processing chamber can be done at about atmospheric pressure as described herein.

The formation of the silicon-containing material 220 (either or both of the providing of the silicon-containing precursor and the contacting of the substrate with the silicon-containing precursor) can be done at a variety of powers and frequencies of the plasma power source. Exemplary powers may range from about 100 Watts to about 5000 Watts. In some embodiments, the power may range from 1000 Watts to 3000 Watts. In embodiments, the power may be less than or about 5000 Watts, such as less than or about 4500 Watts, less than or about 4000 Watts, less than or about 3500 Watts, less than or about 3000 Watts, less than or about 2500 Watts, less than or about 2000 Watts, less than or about 1500 Watts, less than or about 1000 Watts, less than or about 500 Watts, or less. Exemplary frequencies may range from 1 kilohertz (kHz) to 100 megahertz (MHz). In some embodiments, the frequency may range from 1 kHz to 30 MHz. In embodiments, the power may be less than or about 100 MHZ, such as less than or about 95 MHZ, less than or about 90 MHz, less than or about 85 MHz, less than or about 80 MHz, less than or about 75 MHz, less than or about 70 MHz, less than or about 65 MHz, less than or about 60 MHz, less than or about 55 MHz, less than or about 50 MHz, less than or about 45 MHz, less than or about 40 MHz, less than or about 35 MHz, less than or about 30 MHz, less than or about 27 MHz, less than or about 25 MHz, less than or about 20 MHz, less than or about 15 MHz, less than or about 13.56 MHz, less than or about 10 MHz, less than or about 5 MHz, less than or about 1 MHz, less than or about 750 kHz, less than or about 500 kHz, less than or about 350 kHz, less than or about 250 kHz, less than or about 100 kHz, less than or about 10 kHz, or less. In some examples, industry standards may use about 27 MHz, about 13.56 MHz, and/or about 350 kHz.

The first operations may include purging the semiconductor processing chamber (406) as described herein. Purging the semiconductor processing chamber of the silicon-containing precursor can allow for the use of other precursors during the process to fill the feature on the semiconductor substrate.

The first operations may include providing an oxygen-containing precursor plasma (408) as described herein. Providing the oxygen-containing precursor can cause a gap in the feature to close by causing a first side of the silicon-and-oxygen-containing material within the feature to bond with a second side of the silicon-and-oxygen-containing material within the feature as described in relation to at least FIGS. 3A-3B. In some embodiments, the oxygen-containing precursor can include 0₂. In some embodiments, the oxygen-containing precursor can include, mostly include, or solely be a plasma. In some embodiments, the oxygen-containing precursor can include, mostly include, or solely be a gas.

The first operations may include contacting the substrate with the oxygen-containing precursor to form a silicon-and-oxygen-containing material within the feature defined on the substrate (410) as described herein. Forming the silicon-and-oxygen-containing material within the feature can include providing oxygen to the atomic layer of silicon.

In some examples, the oxygen-containing precursor plasma is provided with a power characteristic and at a pressure characteristic. In some examples, the values of the power characteristic and the pressure characteristic are based at least in part on a frequency characteristic of the plasma power source of the semiconductor processing chamber. In some examples, the values of the power characteristic and the pressure characteristic are based at least in part on a frequency characteristic of the oxygen-containing precursor plasma. The power characteristic, the pressure characteristic, and the frequency characteristic can be configured to increase radical density (for example, the radical density of the oxygen-containing precursor plasma and/or the silicon-and-oxygen-containing material) to a sufficient threshold. The power characteristic, the pressure characteristic, and the frequency characteristic can be configured to provide kinetic energy (for example, to the oxygen-containing precursor plasma and/or the silicon-and-oxygen-containing material) within a range with a minimum threshold and a maximum threshold.

As described herein, gapfill operations minimize seams (and/or the precursors and/or formed materials) that may require a minimum amount of radical density and a sufficiently optimal (for example, not too much and not too little) kinetic energy. As such, the power characteristic, pressure characteristic, and frequency characteristic need to be within certain ranges to minimize seam formation and/or improve seam performance. In some examples, increasing the frequency characteristic increases the radical density. In some examples, decreasing the frequency characteristic decreases the radical density. In some examples, increasing the frequency characteristic decreases the kinetic energy. In some examples, decreasing the frequency characteristic increases the kinetic energy. In some examples, increasing the pressure characteristic decreases the kinetic energy. In some examples, decreasing the pressure characteristic increases the kinetic energy. In some examples, increasing the power characteristic increases both the radical density and the kinetic energy. In some examples, decreasing the power characteristic decreases both the radical density and the kinetic energy.

In this way, an increase in the power characteristic can be paired with an increase in the pressure characteristic such that the power characteristic provides both increased radical density (to above a threshold) and kinetic energy, but the increased pressure characteristic can lower the kinetic energy to within the range of a minimum threshold and a maximum threshold. Similarly, an increase in the power characteristic can be paired with an increase in the frequency characteristic such that the power characteristic provides both increased radical density (to above a threshold) and kinetic energy, but the increased frequency characteristic can lower the kinetic energy to within the range of a minimum threshold and a maximum threshold. The increased frequency characteristic can also increase radical density to aid in raising the radical density above the threshold.

In some examples, multiple frequency characteristics can be used. For example, a first power source can have a first frequency characteristic and a second power source can have a second frequency characteristic. The first frequency characteristic can be a for a higher frequency in order to increase the radical density. The second frequency characteristic can be a lower frequency in order to increase the kinetic energy. The combination of the frequency characteristics can provide the benefits of both increased kinetic energy and increased radical density.

As previously discussed, plasma effluents of the silicon-containing precursor and/or the oxygen-containing precursor may be generated. In some embodiments, only plasma effluents of the oxygen-containing may be generated, while the silicon-containing precursor may be plasma-free. By generating plasma effluents of one or more precursors, directionality of the effluent may be increased, which may encourage deposition of material that is seam free and void free. When plasma is generated, one or more inert precursors, such as argon, helium, or nitrogen, may be provided with the precursor to assist in generating plasma effluents as well as distribute the precursor. The plasma of the inert precursor may be a capacitively coupled plasma (CCP) plasma, a plasma formed in a remote plasma source (RPS), or a microwave plasma.

After forming the silicon-and-oxygen-containing material 230, the methods described herein may include performing a post-formation treatment. The post-formation treatment may include providing an inert precursor to the semiconductor processing chamber, generating plasma effluents of the inert precursor, and contacting the silicon-and-oxygen-containing material 230 with plasma effluents of the inert precursor. The inert precursor may be or include any inert precursors, such as argon, helium, or nitrogen. Similar to the optional plasma of the first precursor, the second precursor, and/or the third precursor, the plasma of the inert precursor may be a capacitively coupled plasma (CCP) plasma, a plasma formed in a remote plasma source (RPS), or a microwave plasma. The plasma effluents of the inert precursor may regenerate reactive species on surfaces of exposed materials, which may allow for continued growth to occur. The plasma effluents of the inert precursor may densify the material by outgassing hydrogen.

The formation of the silicon-and-oxygen-containing material 230 may (either or both of the providing of the oxygen-containing precursor and the contacting of the substrate with the oxygen-containing precursor) can be done at a variety of temperatures (for example, the temperature of the substrate 205, the temperature of the processing chamber, and/or the temperature of the precursors that flow into the processing region). Exemplary temperatures for the substrate, processing chamber, and/or precursors during the operations described herein may be greater than or about 50° C., greater than or about 75° C., greater than or about 100° C., greater than or about 125° C., greater than or about 150° C., greater than or about 175° C., greater than or about 200° C., greater than or about 250° C., greater than or about 300° C., greater than or about 350° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., greater than or about 625° C., greater than or about 650° C., greater than or about 675° C., greater than or about 700° C., greater than or about 725° C., greater than or about 750° C., greater than or about 775° C., greater than or about 800° C., greater than or about 825° C., greater than or about 850° C., greater than or about 875° C., greater than or about 900° C., greater than or about 925° C., greater than or about 950° C., greater than or about 975° C., greater than or about 1000° C., or higher. In some embodiments, exemplary temperatures can range from 400° C.-1000° C. In some embodiments, exemplary temperatures can range from 400° C.-700° C. In some embodiments, exemplary temperatures can range from 600° C.-1000° C. In some embodiments, exemplary temperatures can range from 500° C.-600° C. In some embodiments, an exemplary temperature can be 550° C. By maintaining the substrate temperature elevated, such as above or about 400° C. in some embodiments, an increased number of nucleation sites may be available along the substrate 205, which may improve formation and reduce void formation by improving coverage at each location.

The formation of the silicon-and-oxygen-containing material 230 (either or both of the providing of the oxygen-containing precursor and the contacting of the substrate with the oxygen-containing precursor) can be done at a variety of pressures in the processing chamber. The formation rate of the silicon-and-oxygen-containing material 230 may also depend on the pressure in the processing chamber. Exemplary pressures in the processing region may range from about 1 Torr to about 100 Torr. In some embodiments, the pressures in the processing region may range from 2 to 20 Torr. In embodiments, the pressure may be less than or about 20 Torr, such as less than or about 19 Torr, less than or about 18 Torr, less than or about 17 Torr, less than or about 16 Torr, less than or about 15 Torr, less than or about 14 Torr, less than or about 13 Torr, less than or about 12 Torr, less than or about 11 Torr, less than or about 10 Torr, less than or about 9 Torr, less than or about 8 Torr, less than or about 7 Torr, less than or about 6 Torr, less than or about 5 Torr, less than or about 4 Torr, less than or about 3 Torr, less than or about 2 Torr, less than or about 1 Torr, or less. In some embodiments, part of the processes in the processing chamber can be done at about atmospheric pressure as described herein. In some embodiments, part of the processes in the processing chamber can be done at about atmospheric pressure as described herein.

The formation of the silicon-and-oxygen-containing material 230 (either or both of the providing of the silicon-containing precursor and the contacting of the substrate with the silicon-containing precursor) can be done at a variety of powers and frequencies of the plasma power source. Exemplary powers may range from about 100 Watts to about 5000 Watts. In some embodiments, the power may range from 1000 Watts to 3000 Watts. In embodiments, the power may be less than or about 5000 Watts, such as less than or about 4500 Watts, less than or about 4000 Watts, less than or about 3500 Watts, less than or about 3000 Watts, less than or about 2500 Watts, less than or about 2000 Watts, less than or about 1500 Watts, less than or about 1000 Watts, less than or about 500 Watts, or less. Exemplary frequencies may range from 1 kilohertz (kHz) to 100 megahertz (MHz). In some embodiments, the frequency may range from 1 kHz to 30 MHz. In embodiments, the power may be less than or about 100 MHz, such as less than or about 95 MHz, less than or about 90 MHz, less than or about 85 MHz, less than or about 80 MHz, less than or about 75 MHz, less than or about 70 MHz, less than or about 65 MHz, less than or about 60 MHz, less than or about 55 MHz, less than or about 50 MHz, less than or about 45 MHz, less than or about 40 MHz, less than or about 35 MHz, less than or about 30 MHz, less than or about 27 MHz, less than or about 25 MHz, less than or about 20 MHz, less than or about 15 MHz, less than or about 13.56 MHz, less than or about 10 MHZ, less than or about 5 MHZ, less than or about 1 MHz, less than or about 750 kHz, less than or about 500 kHz, less than or about 350 kHz, less than or about 250 kHz, less than or about 100 kHz, less than or about 10 kHz, or less. In some examples, industry standards may use about 27 MHz, about 13.56 MHZ, and/or about 350 kHz.

In some examples, the frequency characteristic can be between 10 MHz and 15 MHz (for example, 13.56 MHz). In such examples with the frequency characteristic between 10 MHz and 15 MHz, the power characteristic can be between 1000 Watts and 2000 Watts. In such examples with the frequency characteristic between 10 MHz and 15 MHz, the pressure characteristic can be between 8 Torr and 15 Torr. In some examples, the frequency characteristic is between about 13.56 MHz, the power characteristic is about 1000 W, and the pressure characteristic is about 10 Torr. In some examples, the frequency characteristic can be between 25 MHz and 30 MHz (for example, 27 MHz). In such examples with the frequency characteristic between 25 MHz and 30 MHz, the power characteristic can be between 1500 Watts and 3000 Watts. In such examples with the frequency characteristic between 25 MHz and 30 MHz, the pressure characteristic can be between 4 Torr and 15 Torr. In some examples, the frequency characteristic is about 27 MHz, the power characteristic is about 2000 Watts, and the pressure characteristic is between 4 Torr and 10 Torr.

In some examples, a first frequency characteristic can be between 25 MHz and 30 MHz (for example, 27 MHz) and a second frequency characteristic can be between 1 kHz and 1 MHz (for example, 350 kHz). The first power associated with the first power source with the first frequency characteristic and the second power associated with the second power source with the second frequency characteristic can be the same or can be different. For example, the first power can be greater than the second power. Alternatively, the second power can be greater than the first power. In some examples, the total power (some operation combining the first power and the second power, such as summing the powers) can be equal to 1000 to 5000 Watts. In some examples, each power (the first power and the second power) can be equal to 1000 to 5000 Watts.

In some examples, a last set of cycles of forming the silicon-and-oxygen-containing material 230 (specifically, either or both of the providing of the silicon-containing precursor and the contacting of the substrate with the silicon-containing precursor) may be performed with the particular pressure, power, and frequency characteristics described herein (such as the frequency characteristic between 10 MHz and 15 MHz, the power characteristic be between 1000 Watts and 2000 Watts, and the pressure characteristic be between 8 Torr and 15 Torr). For example, if the total number of cycles to form the silicon-and-oxygen-containing material is 1000 cycles, the first 900 cycles can be performed without the particular pressure, power, and frequency characteristics described herein, but the last 100 cycles can be performed with the particular pressure, power, and frequency characteristics described herein. In some examples, the last 50% or less of the cycles are performed with the particular pressure, power, and frequency characteristics. In some examples, the percentage of cycles performed with the particular pressure, power, and frequency characteristics can be the last 50% or less of the cycles, the last 45% or less of the cycles, the last 40% or less of the cycles, the last 35% or less of the cycles, the last 30% or less of the cycles, the last 25% or less of the cycles, the last 20% or less of the cycles, the last 15% or less of the cycles, the last 10% or less of the cycles, or the last 5% or less of the cycles, or less. In some examples, the number of cycles performed with the particular pressure, power, and frequency characteristics can be the last 1000 cycles or less. In some examples, the number of cycles performed with the particular pressure, power, and frequency characteristics can be the last 1000 cycles or less, the last 900 cycles or less, the last 900 cycles or less, the last 800 cycles or less, the last 700 cycles or less, the last 600 cycles or less, the last 500 cycles or less, the last 400 cycles or less, the last 300 cycles or less, the last 200 cycles or less, the last 100 cycles or less, the last 50 cycles or less, or less.

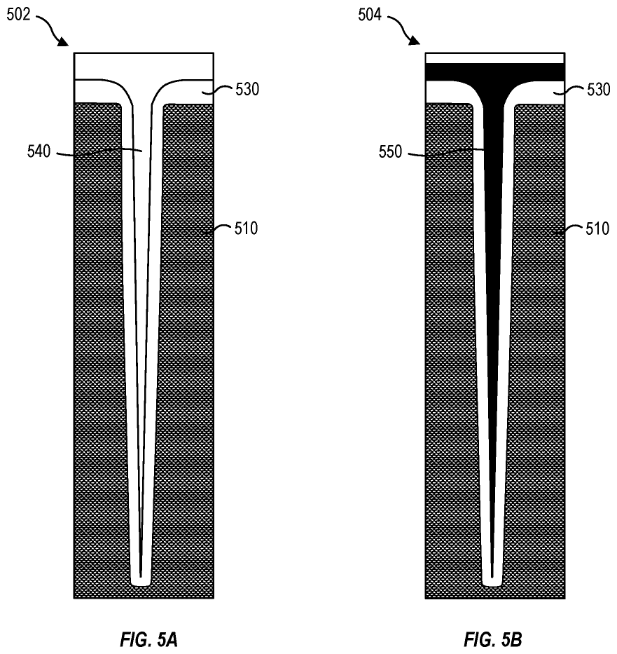

FIGS. 5A-5B schematically illustrate processing methods for improving seam performance according to some embodiments of the present technology. Cross-section 502 illustrates forming silicon-and-oxygen containing material 530 (for example, the silicon-and-oxygen-containing material 230 of FIG. 2) that is deposited into the one or more materials 510 (for example, the one or more materials 210 of FIG. 2). In FIG. 5A, a space 540 can be seen between the two sides of the silicon-and-oxygen-containing material 530 deposited into the feature. The silicon-and-oxygen-containing material 530 can be roughly uniform across the surface of the one or more materials 510.

In FIG. 5B, a silicon-containing-non-oxide-containing material 550 can be deposited to fill the space 540. The silicon-containing-non-oxide-containing material 550 may not include oxygen. The silicon-containing-non-oxide-containing material 550 can be deposited via any conformal process, for example atomic layer deposition or chemical vapor deposition. The silicon-containing-non-oxide-containing material 550 can be silicon (for example, high purity silicon), silicon carbide, or silicon nitride. When an etchant (for example, a buffer oxide etchant that etches the silicon-and-oxygen-containing material 530) is applied to the silicon-and-oxygen-containing material 530 and the silicon-containing-non-oxide-containing material 550, a seam may not be noticeable. The atomic layer deposition of the silicon-and-oxygen containing material 530 can be used to form a sufficiently compressive gapfill. The conformal deposition of the silicon-containing-non-oxide-containing material 550 can be used to make the sufficiently compressive gapfill have high seam performance by not forming a seam.

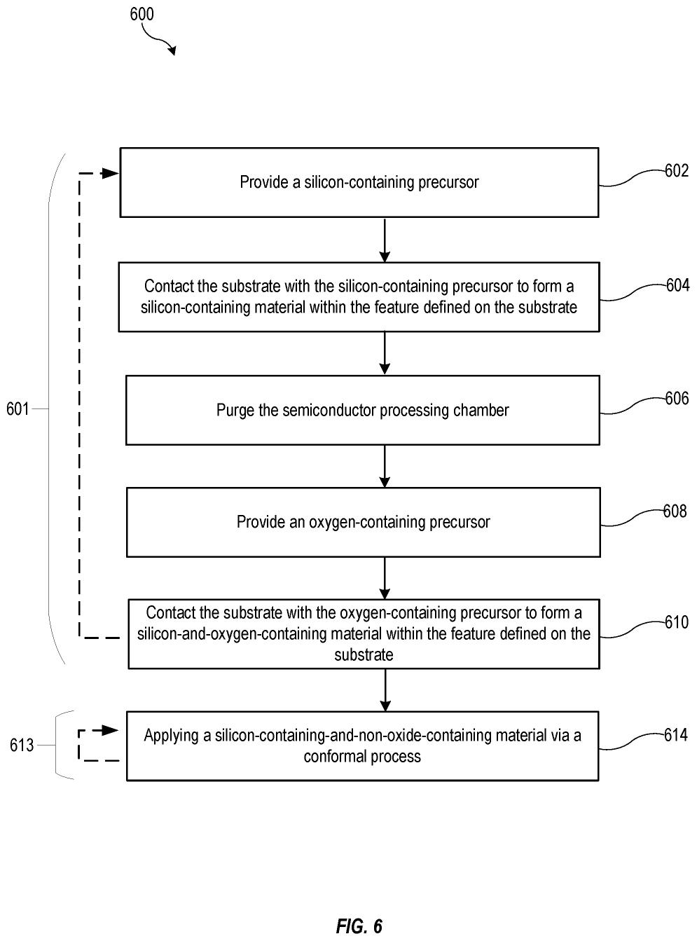

FIG. 6 illustrates an example flowchart 600 of a method of filling a feature on a semiconductor substrate as described herein. This method may be carried out by the controller that generates the signals for controlling the processing chamber and other elements as illustrated above in FIGS. 2A-2D and 5A-5B. This method may be carried out by a controller having processors that execute instructions to perform these operations.

The method may include performing a process to fill the feature on the semiconductor substrate in a semiconductor processing chamber. The process can include repeatedly performing second operations (601) as described herein. For example, the second operations can be repeated for a number of cycles as described herein. Additionally, parts of the second operations can be repeated for different numbers of cycles such that one part of the second operations can be repeated for a first number of cycles while a second part of the second operations can be repeated for a second number of cycles. In some embodiments, the feature can be characterized by an aspect ratio of greater than or about 10:1 as described herein.

In some embodiments, the second operations can be performed at a first pressure level. In some embodiments, the first pressure level can be less than or about 100 Torr as described herein. Exemplary pressures in the processing region may range from about 1 Torr to about 100 Torr. In some embodiments, the pressures in the processing region may range from 2 to 20 Torr. In embodiments, the pressure may be less than or about 20 Torr, such as less than or about 19 Torr, less than or about 18 Torr, less than or about 17 Torr, less than or about 16 Torr, less than or about 15 Torr, less than or about 14 Torr, less than or about 13 Torr, less than or about 12 Torr, less than or about 11 Torr, less than or about 10 Torr, less than or about 9 Torr, less than or about 8 Torr, less than or about 7 Torr, less than or about 6 Torr, less than or about 5 Torr, less than or about 4 Torr, less than or about 3 Torr, less than or about 2 Torr, less than or about 1 Torr, or less. In some embodiments, part of the processes in the processing chamber can be done at about atmospheric pressure as described herein.

In some embodiments, the second operations can be performed at a first temperature. In some embodiments, the first temperature can be a temperature greater than or about 400° C. as described herein. In some embodiments, the second operations can be performed at a temperature greater than or about 400° C. as described herein. Exemplary temperatures for the substrate, processing chamber, and/or precursors during the operations described herein may be greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., greater than or about 625° C., greater than or about 650° C., greater than or about 675° C., greater than or about 700° C., greater than or about 725° C., greater than or about 750° C., greater than or about 775° C., greater than or about 800° C., greater than or about 825° C., greater than or about 850° C., greater than or about 875° C., greater than or about 900° C., greater than or about 925° C., greater than or about 950° C., greater than or about 975° C., greater than or about 1000° C., or higher. In some embodiments, exemplary temperatures can range from 400° C.-1000° C. In some embodiments, exemplary temperatures can range from 400° C.-700° C. In some embodiments, exemplary temperatures can range from 600° C.-1000° C.

The second operations may include providing a silicon-containing precursor (602) to a semiconductor processing chamber (for example, the processing chamber 100 of FIG. 1) as described in relation to at least FIGS. 2A-2D. The silicon-containing precursor can be a first precursor as described herein.

The second operations may include contacting the substrate with the silicon-containing precursor to form a silicon-containing material within the feature defined on the substrate (604) as described herein. Forming the silicon-containing material within the feature can include forming an atomic layer of silicon on an exposed surface of the feature. The exposed surface of the feature can include two or more sides of the feature, for example sides that are opposite of each other.

The second operations may include purging the semiconductor processing chamber (606) as described herein. Purging the semiconductor processing chamber of the silicon-containing precursor can allow for the use of other precursors during the process to fill the feature on the semiconductor substrate.

The second operations may include providing an oxygen-containing precursor (608) as described herein. In some embodiments, the oxygen-containing precursor can include, mostly include, or solely be a plasma. In some embodiments, the oxygen-containing precursor can include, mostly include, or solely be a gas.

The second operations may include contacting the substrate with the oxygen-containing precursor to form a silicon-and-oxygen-containing material within the feature defined on the substrate (610) as described herein. Forming the silicon-and-oxygen-containing material within the feature can include providing oxygen to the atomic layer of silicon.

The process can also include repeatedly performing third operations (613) as described herein. For example, the third operations can be repeated for a number of cycles as described herein. Additionally, parts of the third operations can be repeated for different numbers of cycles such that one part of the third operations can be repeated for a first number of cycles while a second part of the second operations can be repeated for a second number of cycles. In some embodiments, the feature can be characterized by an aspect ratio of greater than or about 10:1 as described herein. The third operations can be performed in the same semiconductor processing chamber as the second operations.

In some embodiments, the third operations can be performed at a second pressure level. In some embodiments, the second pressure level can be less than or equal to 100 Torr. Exemplary pressures in the processing region may range from about 1 Torr to about 100 Torr. In some embodiments, the pressures in the processing region may range from 2 to 20 Torr. In embodiments, the pressure may be less than or about 20 Torr, such as less than or about 19 Torr, less than or about 18 Torr, less than or about 17 Torr, less than or about 16 Torr, less than or about 15 Torr, less than or about 14 Torr, less than or about 13 Torr, less than or about 12 Torr, less than or about 11 Torr, less than or about 10 Torr, less than or about 9 Torr, less than or about 8 Torr, less than or about 7 Torr, less than or about 6 Torr, less than or about 5 Torr, less than or about 4 Torr, less than or about 3 Torr, less than or about 2 Torr, less than or about 1 Torr, or less. In some embodiments, part of the processes in the processing chamber can be done at about atmospheric pressure as described herein.

In some embodiments, the third operations can be performed at a second temperature. In some embodiments, the second temperature can be a temperature greater than or about 400° C. as described herein. In some embodiments, first temperature and the second temperature can be different. In some embodiments, the third operations can be performed at a temperature greater than or about 400° C. as described herein. Exemplary temperatures for the substrate, processing chamber, and/or precursors during the operations described herein may be greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., greater than or about 625° C., greater than or about 650° C., greater than or about 675° C., greater than or about 700° C., greater than or about 725° C., greater than or about 750° C., greater than or about 775° C., greater than or about 800° C., greater than or about 825° C., greater than or about 850° C., greater than or about 875° C., greater than or about 900° C., greater than or about 925° C., greater than or about 950° C., greater than or about 975° C., greater than or about 1000° C., or higher. In some embodiments, exemplary temperatures can range from 400° C.-1000° C. In some embodiments, exemplary temperatures can range from 400° C.-700° C. In some embodiments, exemplary temperatures can range from 600° C.-1000° C.

The third operations may include applying silicon-containing-non-oxide-containing material (614) via a conformal process as described herein. For example, the silicon-containing-non-oxide-containing material can be the silicon-containing-non-oxide-containing material 550 of FIG. 5B. In some embodiments, the silicon-containing-non-oxide-containing material 550 can include silicon (Si) such as high purity silicon or monocrystalline silicon. In some embodiments, the silicon-containing-non-oxide-containing material 550 can include silicon carbide (SiC). In some embodiments, the silicon-containing-non-oxide-containing material 550 can include silicon nitride (SiN). In some embodiments, the oxygen-containing precursor can include, mostly include, or solely be a plasma. In some embodiments, the oxygen-containing precursor can include, mostly include, or solely be a gas.

The silicon-containing-non-oxide-containing material can be applied via any conformal process. In some examples, the silicon-containing-non-oxide-containing material can be applied via chemical vapor deposition. In some examples, the silicon-containing-non-oxide-containing material can be applied by atomic layer deposition. For example, atomic layer deposition of the silicon-containing-non-oxide-containing material can include alternating of providing and contact of different precursors as described herein.

In some embodiments, the second operations as described herein can precede the third operations. For example, the second operations can be repeatedly performed prior to repeatedly performing the third operations. In some embodiments, the percentage of total cycles for the second operations and the third operations can be apportioned such that the second operations occur for about 90% of the total cycles, such that the second operations occur for about 80% of the total cycles, such that the second operations occur for about 70% of the total cycles, such that the second operations occur for about 60% of the total cycles, such that the second operations occur for about 50% of the total cycles, such that the second operations occur for about 40% of the total cycles, such that the second operations occur for about 30% of the total cycles, such that the second operations occur for about 20% of the total cycles, such that the first operations occur for about 10% of the total cycles, or less.

In some embodiments, there may be a determination of a target thickness of the silicon-and-oxygen-containing material and/or a target thickness of the silicon-containing-non-oxide-containing material. If a target thickness of the silicon-and-oxygen-containing material has not been achieved, another cycle of the second operations may occur. If a target thickness of the silicon-and-oxygen-containing material has been achieved, a cycle of the third operations can be performed. If a target thickness of the silicon-containing-non-oxide-containing material has been achieved, the third operations may cease. Exemplary numbers of cycles for the second operations may include 1 cycle, or may include greater than 2 cycles, 5 cycles, 10 cycles, 25 cycles, 50 cycles, 100 cycles, 1000 cycles, 2000 cycles, 3000 cycles, 4000 cycles, 5000 cycles, 6000 cycles, 7000 cycles, 8000 cycles, 9000 cycles, 10000 cycles or more. Additional exemplary ranges for the number of cycles may include 50 cycles to 2000 cycles, 50 cycles to 1000 cycles, and 100 cycles to 750 cycles, 1000 to 2000 cycles, 2000 to 3000 cycles, 3000 to 4000 cycles, 4000 to 5000 cycles, 5000 to 6000 cycles, 6000 to 7000 cycles, 7000 to 8000 cycles, 8000 to 9000 cycles, 9000 to 10000 cycles, and/or any combination of these ranges. For example, some embodiments may use between 6000 and 8000 cycles for a 1 μm wide gap structure. Exemplary ranges of target thickness to discontinue further cycles of forming silicon-and-oxygen-containing material include less than or about 1.0 microns. Additional exemplary thickness ranges may include less than or about 1.0 microns, less than or about 0.9 microns, less than or about 0.8 microns, less than or about 0.7 microns, less than or about 0.6 microns, less than or about 0.5 microns, less than or about 0.4 microns, less than or about 0.3 microns, less than or about 0.2 microns, less than or about 0.1 microns, or less, including any fraction of any of the stated numbers. Exemplary numbers of cycles for the third operations may include 1 cycle, or may include greater than 2 cycles, 5 cycles, 10 cycles, 25 cycles, 50 cycles, 100 cycles, 1000 cycles, 2000 cycles, 3000 cycles, 4000 cycles, 5000 cycles, 6000 cycles, 7000 cycles, 8000 cycles, 9000 cycles, 10000 cycles or more. Additional exemplary ranges for the number of cycles may include 50 cycles to 2000 cycles, 50 cycles to 1000 cycles, and 100 cycles to 750 cycles, 1000 to 2000 cycles, 2000 to 3000 cycles, 3000 to 4000 cycles, 4000 to 5000 cycles, 5000 to 6000 cycles, 6000 to 7000 cycles, 7000 to 8000 cycles, 8000 to 9000 cycles, 9000 to 10000 cycles, and/or any combination of these ranges. For example, some embodiments may use between 6000 and 8000 cycles for a 1 μm wide gap structure. Exemplary ranges of target thickness to discontinue further cycles of forming the silicon-containing-non-oxide-containing material include less than or about 1.0 microns. Additional exemplary thickness ranges may include less than or about 1.0 microns, less than or about 0.9 microns, less than or about 0.8 microns, less than or about 0.7 microns, less than or about 0.6 microns, less than or about 0.5 microns, less than or about 0.4 microns, less than or about 0.3 microns, less than or about 0.2 microns, less than or about 0.1 microns, or less, including any fraction of any of the stated numbers.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursor, and reference to “the material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of filling a feature on a semiconductor substrate, the method comprising:
performing a process to fill the feature on the semiconductor substrate in a semiconductor processing chamber, wherein the process comprises repeatedly performing first operations comprising:
providing a silicon-containing precursor;
contacting the substrate with the silicon-containing precursor to form a silicon-containing material within the feature defined on the substrate;
purging the semiconductor processing chamber;
providing an oxygen-containing precursor plasma with a power characteristic and at a pressure characteristic based at least in part on a frequency characteristic of a plasma power source of the semiconductor processing chamber, wherein the power characteristic, the pressure characteristic, and the frequency characteristic are configured to increase radical density of the oxygen-containing precursor plasma and provide kinetic energy within a range to ions of the oxygen-containing precursor plasma; and
contacting the substrate with the oxygen-containing precursor to form a silicon-and-oxygen-containing material within the feature defined on the substrate.

2. The method of claim 1, wherein providing the oxygen-containing precursor with the power characteristic, pressure characteristic, and frequency characteristic causes a gap in the feature to close by causing a first side of the silicon-and-oxygen-containing material within the feature to bond with a second side of the silicon-and-oxygen-containing material within the feature.

3. The method of claim 1, wherein forming the silicon-containing material within the feature includes forming an atomic layer of silicon on an exposed surface of the feature; and
wherein forming the silicon-and-oxygen-containing material within the feature includes providing oxygen to the atomic layer of silicon.

4. The method of claim 1, wherein the frequency characteristic is within a range of about 25 MHz to 30 MHz.

5. The method of claim 4, wherein the pressure characteristic is within a second range of about 4 Torr to about 15 Torr.

6. The method of claim 5, wherein the power characteristic is within a third range of about 1500 Watts and about 3000 Watts.

7. The method of claim 4, wherein providing the oxygen-containing precursor plasma includes providing the oxygen-containing precursor plasma at a second frequency characteristic of a second plasma power source of the semiconductor processing chamber, the second frequency characteristic being with in a fourth range of about 1 kHz to 1 MHz.

8. The method of claim 1, wherein the feature is characterized by an aspect ratio of greater than or about 10:1.

9. The method of claim 1, wherein the oxygen-containing precursor comprises 0₂.

10. A method of filling a feature on a semiconductor substrate, the method comprising:
performing a process to fill the feature on the semiconductor substrate in a semiconductor processing chamber, wherein the process comprises repeatedly performing first operations comprising:
providing a silicon-containing precursor;
contacting the substrate with the silicon-containing precursor to form a silicon-containing material within the feature defined on the substrate;
purging the semiconductor processing chamber;
providing an oxygen-containing precursor; and
contacting the substrate with the oxygen-containing precursor by forming a plasma with a frequency characteristic and a power characteristic and at a pressure characteristic, wherein the power characteristic, the pressure characteristic, and the frequency characteristic are configured to provide sufficient radical density and kinetic energy, wherein contacting the substrate with the oxygen-containing precursor forms a silicon-and-oxygen-containing material within the feature defined on the substrate.

11. The method of claim 10, wherein contacting the silicon-and-oxygen-containing material with the oxygen-containing precursor with the frequency characteristic, the power characteristic, and at the pressure characteristic causes a gap in the feature to close by causing a first side of the silicon-and-oxygen-containing material within the feature to bond with a second side of the silicon-and-oxygen-containing material within the feature.

12. The method of claim 10, wherein the power characteristic is within a range of about 1000 Watts and about 2000 Watts.

13. The method of claim 10, wherein the pressure characteristic is within a second range of about 8 Torr to about 15 Torr.

14. The method of claim 10, wherein the frequency characteristic is within a third range of about 10 MHz to 15 MHz.

15. The method of claim 10, wherein the process is performed at a temperature greater than or about 400° C.

16. A method of filling a feature on a semiconductor substrate, the method comprising:
performing a process to fill the feature on the semiconductor substrate in a semiconductor processing chamber, wherein the process comprises repeatedly performing first operations at a first pressure level, the first operations comprising:
providing a silicon-containing precursor;
contacting the substrate with the silicon-containing precursor to form a silicon-containing material within the feature defined on the substrate;
purging the semiconductor processing chamber;
providing an oxygen-containing precursor; and
providing an oxygen-containing precursor; and
wherein the process to fill the feature further comprises second operations, the second operations comprising applying a silicon-containing-and-non-oxide-containing material via a conformal application process.

17. The method of claim 16, wherein the conformal application process is a chemical vapor deposition process.

18. The method of claim 16, wherein the conformal application process is an atomic layer deposition process.

19. The method of claim 16, wherein the silicon-containing-and-non-oxide-containing material comprises at least one of: SiC, SiN, and high-purity silicon.

20. The method of claim 16, wherein the second operations are performed in the semiconductor processing chamber.
